(19) United States
(12) Patent Application Publication
(10) Pub. No.: US 2003/0060013 A1
(43) Pub. Date: Mar. 27, 2003

(54) METHOD OF MANUFACTURING TRENCH FIELD EFFECT TRANSISTORS WITH TRENCHED HEAVY BODY

(76) Inventors: BRUCE D. MARCHANT, MURRAY, UT (US); DEAN PROBST, WEST JORDAN, UT (US); PAUL THORUP, WEST JORDAN, UT (US); DENSEN CAO, SANDY, UT (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(21) Appl. No.: 09/405,210

(22) Filed: Sep. 24, 1999

(51) Int. Cl. H01L 21/336

(52) U.S. Cl. 438/270

(57) ABSTRACT

A process for manufacturing trench field effect transistors improves transistor ruggedness without compromising transistor cell pitch. Instead of a high dose implant and heat cycle, the process of the invention forms the transistor heavy body by etching a trench into the body region and filling the heavy body trench with high conductivity material such as metal that makes contact to both the body and the source region.

### BACKGROUND OF THE INVENTION

The present invention relates in general to semiconductor technology, and in particular to trench field effect transistors and their methods of manufacture.

FIG. 1 is a simplified cross section of a portion of an exemplary trench field effect transistor. Trenches 100 extend into a substrate 102 which typically includes an epitaxial layer (not shown). Each trench 100 is lined with an electrically insulating or dielectric material 104, such as silicon dioxide (SiO₂), that acts as the gate dielectric. The trench is then filled with a conductive material 106, such as polysilicon, that provides the transistor gate terminal. A well or body region 108 is formed on top of substrate 102, and source regions 110 are formed on both sides of each trench 100 as shown. A region referred to as heavy body 112 extends between source regions between adjacent trenches. Dielectric material 114 covers trench openings and its adjacent source regions. A layer of metal 116 blankets the top surface of the silicon. For an n-channel MOSFET, the doping polarities for the various regions would be as follows: n-type substrate 102 (providing the drain terminal of the transistor), p-type body 108, p+ heavy body 112, and n+ source 110. The active region of the field effect transistor is thus formed between source 110 and substrate (or drain) 102 along the sides of each trench (or gate) 100.

In the design of trench field effect transistors, it is desirable to have a heavily doped body region 112 that extends below source region 110. This heavy body provides a low resistance path around the source area and helps keep the body-source junction from ever becoming forward biased. The ability of the transistor to avoid turning on the parasitic bipolar transistor is commonly referred to as ruggedness. A deep heavy body also helps move the electric field and its breakdown current path away from the silicon/dielectric (Si/SiO₂) interface at the trench corners. Moving the electric field away from the trench comers reduces the possibility of damage caused to the gate oxide by hot electrons.

Current technologies improve transistor ruggedness and gate oxide integrity by forming a heavy body using a high energy implant followed by a temperature cycle to drive the heavy body dopant to the desired depth. The temperature cycle that drives in the dopants, however, also causes lateral diffusion of the heavy body region. Laterally diffused heavy body dopants may interfere with the active channel area and disturb the transistor threshold voltage. To avoid this type of undesirable threshold variations caused by lateral diffusion of the heavy body dopants places a limit on the minimum cell pitch (distance between adjacent trenches). A larger minimum cell pitch not only reduces the cell density per die, it contributes to the drain-to-source on resistance R_{DSon} of the trench transistor which adversely affects the performance of the transistor.

There is therefore a need for trench MOSFET structures and methods of manufacture that improve ruggedness without compromising cell pitch or the value of R_{DSon}.

### SUMMARY OF THE INVENTION

The present invention provides structures and methods of manufacture for a trench field effect transistor with a trenched body. Broadly, instead of a high energy, high dose implant followed by diffusion, the heavy body according to the present invention is formed by a trench that extends into the body. The trench is then filled with high conductivity material such as metal. In a specific embodiment, after etching the body trench, source metal is deposited into the trench, providing a vertical contact to the source region and a planar contact to the body region. The trenched heavy body formed by the metal plug into silicon provides a lower resistance path around the source region as compared to the implanted heavy body. Further, by eliminating the lateral diffusion, the trenched body according to the present invention allows for reduced cell pitch and lower R_{DSon}.

Accordingly, in one embodiment, the present invention provides a method of manufacturing a trench field effect transistor on a substrate having a first conductivity type, the method including the steps of forming a first trench extending into the substrate; lining the first trench with dielectric material; substantially filling the first trench with conductive material to form a gate electrode of the field effect transistor; forming a body region having a second conductivity type in the substrate; forming a source region having the first conductivity type inside the body region and adjacent to the first trench; forming a second trench adjacent to said source region and extending into the body region below the source region; and filling the second trench with high conductivity material for making contact to the body region. The high conductivity material making contact to the body region also makes contact to the source region.

In another embodiment, the present invention provides a trench field effect transistor including a substrate having a first conductivity type, a body region having a second conductivity type and disposed over the substrate, a gate trench extending through the body region and into the substrate; a source region having the first conductivity type and disposed over the body region and adjacent to the gate trench; and a body trench extending into the body region, wherein the body trench is substantially filled with high conductivity material for making contact to the body region. The high conductivity material also makes contact to the source region.

The following detailed description and the accompanying drawings provide a better understanding of the nature and advantages of the trench body field effect transistor and its method of manufacture.

### BRIEF DESCRIPTION OF THE DRAWINGS

FIG. 1 shows a cross section of an exemplary trench field effect transistor;

FIGS. 2A and 2B provide cross-sectional views of a trench field effect transistor according to the present invention before and after the formation of a trenched heavy body;

FIG. 3 is a flow diagram illustrating an exemplary process flow for manufacturing a trench field effect transistor with trenched heavy body according to the present invention; and

FIG. 4 is a cross-sectional view of an alternative embodiment of the trench field effect transistor with a deeper heavy body trench according to the present invention.

### DESCRIPTION OF THE SPECIFIC EMBODIMENTS

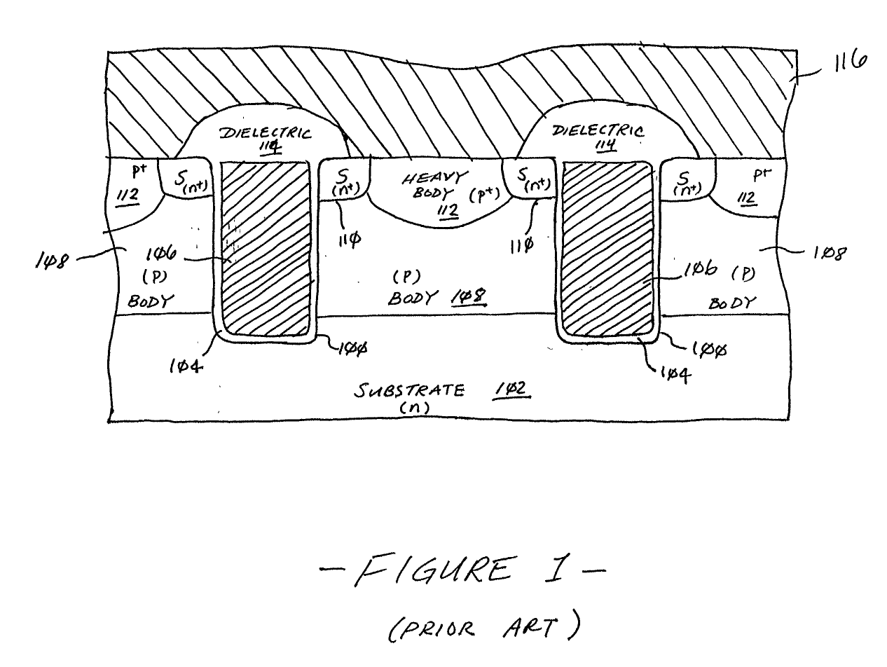

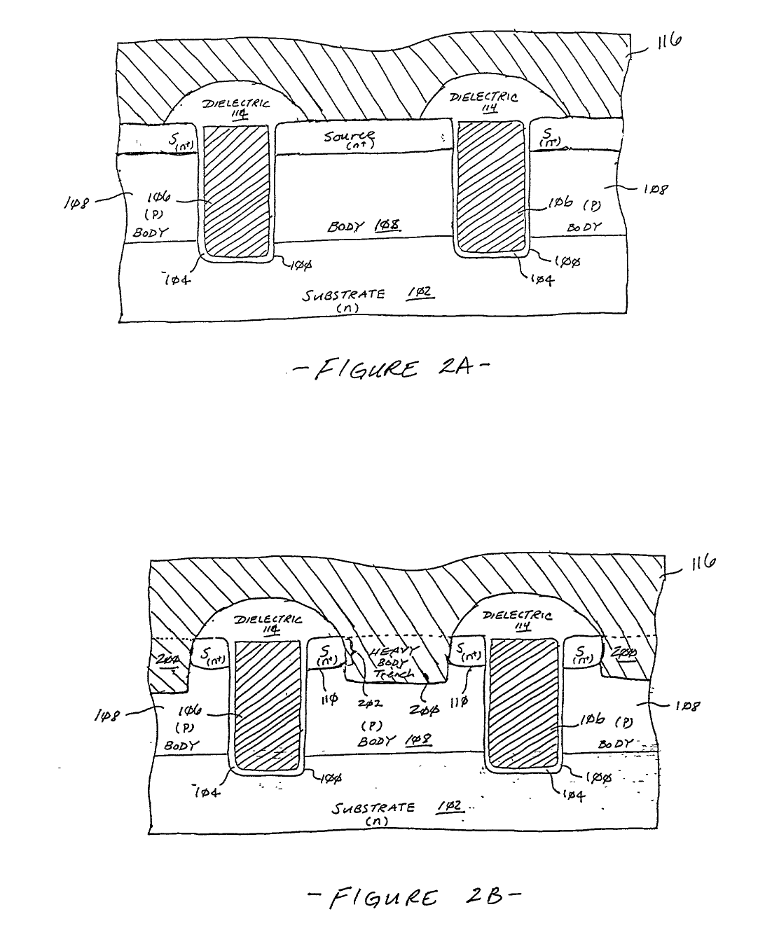

Referring to FIGS. 2A and 2B, there are shown cross-sectional views of a trench field effect transistor according to the present invention before and after the formation of trenched heavy body, respectively. In this exemplary embodiment, with the exception of heavy body structure 200, the remaining aspects of this device may be similar to the trench transistor shown in FIG. 1. The same reference numerals have been used in the various figures herein to denote the same elements. In a preferred embodiment of the present invention, the process of manufacturing the device is completed through the contact layer including the formation of trenches 100, body region 108 and source regions 110 and preferably up to the opening of contact areas for source regions 110, according to known manufacturing processes. The process departs significantly from the conventional approach in formation of the heavy body. Instead of an implant and diffusion cycle, heavy body 200 in the transistor of the present invention is formed by first etching through the source silicon and into body region 108. High conductivity material such as metal (e.g., aluminum) is then deposited into the heavy body trench. Metal layer 116 thus makes vertical contact to source region 110 and planar contact to body 108. Source metal layer 116 extending into the heavy body trench thus replaces the previously implanted heavy body region (112 in FIG. 1).

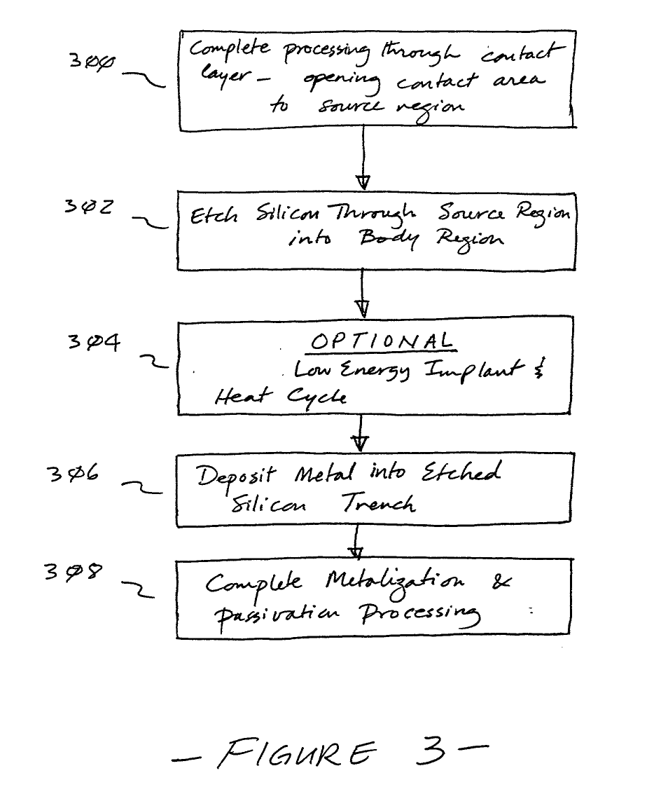

FIG. 3 is a simplified flow diagram illustrating an exemplary process flow for the trench field effect transistor with trenched heavy body according to the present invention. At step 300, all process steps through the contact layer and up to opening contact area for source regions are performed, excluding heavy body doping (implant) and associated heat cycles. A simplified version of the process up to this point typically includes: etching gate trenches into a silicon substrate, lining the gate trenches with dielectric material (e.g., SiO₂) and then filling them with polysilicon, forming body regions by implanting impurities having opposite polarity to that of the substrate, forming source regions by implanting the same impurities as that of the substrate and opening source contact windows. Commonly-assigned U.S. patent application Ser. No. 08/970,221, entitled “Field Effect Transistor and Method of its Manufacture,” by Mo et al., which is incorporated herein by reference, provides a detailed description for a preferred embodiment for the process up to this point. According to the present invention, with the source contact windows exposed, the silicon is etched through the source and into the body to form the heavy body trench. A standard silicon etch process similar to that used for the gate trenches (e.g., anisotropic etch) is used for this step. The etch rate and timing may be adjusted according to the desired trench depth. That is, for a shallower heavy body trench, shorter etch time is used. This may be followed by an optional low energy implant and heat cycle 304 for improved ohmic contact. This step is completely optional, but is recommended for p-channel transistors for better ohmic contact between source metal 116 and n-type body region 108.

Next, source metal such as aluminum is deposited on top of the silicon and inside the heavy body trench. Hot aluminum is preferred to allow for better flow and filling of the trench. In case of deeper heavy body trenches, metal deposition using physical vapor deposition (PVD) process is preferred. In one embodiment, source and body contact resistance is reduced by including a thin barrier metal such as titanium or titanium-nitride underneath the aluminum. Other metal types including platinum, cobalt, tungsten and the like can be used as the thin barrier metal layer. Finally, standard metalization and passivation steps 308 complete the process.

The trench field effect transistor with a trenched heavy body according to the present invention offers a number of advantages over the conventional implanted heavy body trench transistors. The heavy body metal plug into silicon replacing implanted heavy body provides a much lower resistance path around the source region resulting in improved ruggedness. This improved ruggedness is achieved without limiting the minimum cell pitch, which can be reduced as heavy body lateral diffusion is no longer a concern. Furthermore, since the heavy body is formed by an etch process as opposed to an implant plus heat cycle, its dimensions can be more readily controlled by varying etch parameters. Another advantage of the process and structure of the present invention is the reduction in the number of masking steps. By self-aligning the silicon etch heavy body with the source contact layer, at least one masking step is eliminated as compared to conventional implanted heavy body processes where typically separate source and heavy body masks were required.

Yet another advantage of the present invention is its ability to vary the source contact area by varying the source junction depth and/or by changing the slope of the silicon etch through the source region. By, for example, increasing the source implant dose and diffusion, the source junction depth 202 can be increased. An increased source junction depth directly increases the source contact area. Similarly, by varying heavy body trench etch profile, the edge of the source junction can be made slanted for increased source contact area. This increased source contact area reduces R_{DSon} without limiting the cell pitch of the transistor.

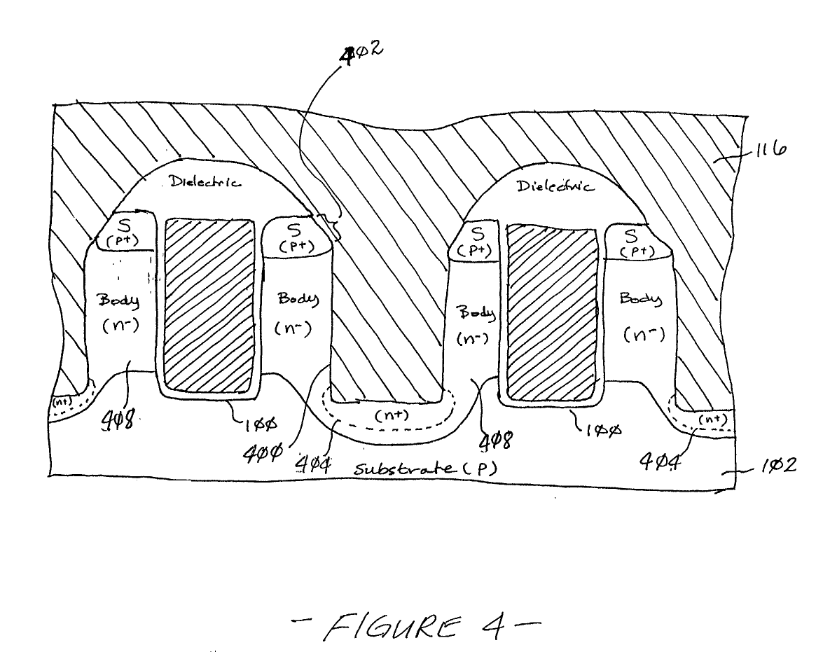

The depth of the heavy body trench according to the present invention may vary depending on the device requirements. Generally, the deeper the heavy body trench is made, the more rugged the transistor becomes. In one embodiment, the heavy body trench is made as deep or even deeper than the gate trench. Referring to FIG. 4, an embodiment of the transistor of the present invention with a deeper heavy body trench is shown. In this embodiment, heavy body trench 400 is made about as deep as gate trench 100, and, for illustrative purposes only, the trench is etched at a slant along the source edges 402 for increased source contact area. The deeper heavy body trench embodiment is particularly suited for p-channel transistors. This is so because source metal 116 (e.g., aluminum) does not typically make good ohmic contact with n-type body 408. In this case, a shallow n+ implant 404 (e.g., 1×10¹⁵ atoms/Cm² of Arsenic at ˜50 KeV, preferably at an angle of zero degrees )underneath heavy body trench 400 helps improve the ohmic contact between source/heavy body metal 116 and body region 408. A similar optional implant may be used for n-channel transistors where a shallow implant (e.g., 1×10¹⁴atoms/Cm² of Boron, at ˜40 KeV) may be used for improved ohmic contact. To reduce the implanted heavy body junction area, the process of the present invention according to this embodiment uses RTP instead of a conventional furnace to activate the heavy body dopant. Even with some lateral diffusion, the deeper heavy body trenches 400 ensure that this shallow implant 404 does not impact the cell pitch adversely. That is, because the bottom of heavy body trench 400 is moved below the active channel area, lateral diffusion of shallow implant 404 is not a concern. Therefore, the deeper heavy body trench in the case of p-channel transistors still allows for the scaling of the transistor.

In conclusion, the present invention provides an improved trench field effect transistor with a trenched heavy body and its method of manufacture. Instead of a heavy implant and temperature cycle, the heavy body of the present invention is formed by etching a trench that is filled by source metal. The trenched heavy body according to the present invention improves transistor ruggedness and overall performance without adversely impacting the transistor cell pitch. While the above is a complete description of specific embodiments of the present invention, various modifications, variations, and alternatives may be employed. For example, a variety of different types of trench processes with different trench characteristics can be used to build the trenches. The polysilicon inside the gate trenches can be, for example, either recessed or level with the surface of the silicon, trench corners may or may not be rounded, gate trenches may be formed before or after the formation of the body regions, etc. Further, the specific embodiment has been described in the context of silicon wafer processing for illustrative purposes only, and other types of substrates, such as a silicon-germanium substrate could be used. Therefore, the scope of this invention is not limited to the embodiments described, and is instead defined by the following claims.

What is claimed is:

1. A method of manufacturing a trench field effect transistor on a substrate having a first conductivity type, the method comprising the steps of:
forming a first trench extending into the substrate;
lining the first trench with dielectric material;
substantially filling the first trench with conductive material to form a gate electrode of the field effect transistor;
forming a body region having a second conductivity type in the substrate;
forming a source region having the first conductivity type inside the body region and adjacent to the first trench;
forming a second trench adjacent to said source region and extending into the body region below the source region; and
filling the second trench with high conductivity material for making contact to the body region.

2. The method of claim 1 wherein the step of filling the second trench with high conductivity material for making contact to the body region also makes contact to the source region.

3. The method of claim 2 wherein the step of filling the second trench with high conductivity material comprises a self-aligned masking step for making contact with both the body region and the source region.

4. The method of claim 2 further comprising a step of implanting impurities of the second conductivity type into the body region under the second trench before the step of filling the second trench.

5. The method of claim 4 further comprising a step of heating the substrate after the step of implanting to drive the impurities further into the body region.

6. The method of claim 2 further comprising a step of forming a thin layer of barrier metal between the high conductivity material and the body region.

7. The method of claim 6 wherein the high conductivity material comprises aluminum and the thin layer of barrier metal comprises titanium.

8. The method of claim 2 wherein the step of forming the second trench comprises a step of etching silicon through the source and body regions.

9. The method of claim 2 wherein the second trench is shallower than the first trench.

10. The method of claim 2 wherein the second trench is approximately as deep as the first trench.

11. The method of claim 2 wherein the second trench is deeper than the first trench.

12. The method of claim 8 wherein the step of etching etches the silicon at an angle resulting in a slanted edge along the etched side of the source region.

13. A process for manufacturing a trench field effect transistor comprising the steps of:
etching a first trench in a substrate having a first conductivity type;
lining the first trench with a layer of dielectric material;
substantially filling the trench with polysilicon;
implanting impurities of a second conductivity type into the substrate to form a body region having the second conductivity type over the substrate;
implanting impurities of the first conductivity type inside the body region to form a source region adjacent to the first trench;
etching a second trench through the source region and into the body region; and
filling the second trench with metal making contact with both the source region and the body region.

14. The process of claim 13 further comprising a step of implanting impurities of the second conductivity type into the body region under the second trench before the step of filling the second trench with metal.

15. The process of claim 13 wherein the step of etching the second trench etches the second trench to a shallower depth than the first trench.

16. The process of claim 13 wherein the step of etching the second trench etches the second trench to substantially a same depth as the first trench.

17. The process of claim 13 wherein the step of etching the second trench etches the second trench deeper than the first trench.
